(19) United States
(12) Patent Application Publication
(10) Pub. No.: US 2022/0251480 A1
(43) Pub. Date: Aug. 11, 2022

(54) COMPOSITIONS FOR REMOVING ETCH RESIDUES, METHODS OF USING AND USE THEREOF

(71) Applicant: Versum Materials US, LLC, Tempe, AZ (US)

(72) Inventors: Laisheng Sun, Gilbert, AZ (US); LILI WANG, Chandler, AZ (US); ALPING WU, Chandler, AZ (US); YI-CHIA LEE, Chupei City (TW); TIANNIU R. CHEN, Westford, MA (US)

(73) Assignee: Versum Materials US, LLC, Tempe, AZ (US)

(21) Appl. No.: 17/597,530

(22) PCT Filed: Jul. 14, 2020
(86) PCT No.: PCT/US2020/041881

§ 371 Date: Jan. 10, 2022

Related U.S. Application Data
(60) Provisional application No. 62/874,477, filed on Jul. 15, 2019.

(51) Int. Cl. C11D 7/32; C11D 7/26; C11D 11/00; G03F 7/42

(52) U.S. Cl. CPC C11D 7/3218; C11D 7/265; G03F 7/426; G03F 7/425; C11D 11/0047

(57) ABSTRACT

This disclosed and claimed subject matter relates to a post etch residue cleaning compositions that include an alkanolamine having two or more or more than two alkanol groups, an alpha-hydroxy acid and water as well as methods for use thereof in microelectronics manufacturing.

### BACKGROUND

### Field

This disclosed and claimed subject matter relates to a post etch residue cleaning composition and method for use thereof in microelectronics manufacturing.

### Background

Numerous steps are involved in the fabrication of microelectronic structures. Within the manufacturing scheme of fabricating integrated circuits, selective etching of different surfaces of the semiconductor is sometimes required. Historically, a number of different types of etching processes to selectively remove materials have been successfully utilized. Moreover, the selective etching of different layers, within the microelectronic structure, is considered an important step in the integrated circuit fabrication process.

In the manufacture of semiconductors and semiconductor microcircuits, it is frequently necessary to coat substrate materials with a polymeric organic substance. Examples of some substrate materials includes, aluminum, titanium, copper, silicon dioxide coated silicon wafer, optionally having metallic elements of aluminum, titanium, or copper, and the like. Typically, the polymeric organic substance is a photoresist material. This is a material which will form an etch mask upon development after exposure to light. In subsequent processing steps, at least a portion of the photoresist is removed from the surface of the substrate. One common method of removing photoresist from a substrate is by wet chemical means. The wet chemical compositions are formulated to remove the photoresist from the substrate with compatible to any metallic circuitry, the inorganic substrate and the substrate itself. Another method of removing photoresist is by a dry ash method where the photoresist is removed by plasma ashing. The residues remaining on the substrate after plasma ash may be the photoresist itself or a combination of the photoresist, underlying substrate and/or etch gases. These residues are often referred to as sidewall polymers, veils or fences.

Increasingly, reactive ion etching (RIE) is the process of choice for pattern transferring during via, metal line and trench formation. For instance, complex semiconductor devices require multiple layers of back end of line interconnect wiring and utilize RIE to produce vias, metal lines and trench structures. Vias are used through the interlayer dielectric to provide contact between one level of silicon, silicide or metal wiring and the next level of wiring. Metal lines are conductive structures used as device interconnects. Trench structures are used in the formation of metal line structures. Vias, metal lines and trench structures typically expose metals and alloys such as Al, Al and Cu alloys, Cu, Ti, TiN, Ta, TaN, W, TiW, silicon or a silicide such as a silicide of tungsten, titanium or cobalt. The RIE process typically leaves a residue or a complex mixture that may include re-sputtered oxide material, organic materials from photoresist, and/or antireflective coating materials used to lithographically define the vias, metal lines and/or trench structures.

Removal of these plasma etching residues is accomplished by exposing the substrates to a formulated solution. Conventional cleaning formulations typically contain a hydroxlyamine, an alkanolamine, water and a corrosion inhibitor. For example, one composition is disclosed in U.S. Pat. No. 5,279,771 where the plasma etching residues left by plasma etching was cleaned by a cleaning solution of water, alkanolamine, and hydroxylamine. Another example disclosed in U.S. Pat. No. 5,419,779 is a plasma etch residue cleaning solution of water, alkanolamine, hydroxylamine and catechol.

Although these formulated solutions can effectively clean plasma etching residues, the presence of hydroxylamine can attack the metallic layers such as titanium layers. One way of controlling the corrosive effect of hydroxylamine in the formulated cleaning solutions is by keeping the water level low with less than approximately 30 wt % of the total solution and using a high concentration of solvent (i.e., a solvent-rich formulated solution). In many of the published patents, catechol has been used as a corrosion inhibitor for aluminum and/or titanium etch. However, there is always a tradeoff between plasma etching residue removal and metal layer corrosion inhibition as some types of the corrosion inhibitors may retard plasma etching residue removal.

Therefore, there remains a need for a formulation that does not contain hydroxylamine but that can nevertheless remove plasma etch residues from substrates without causing deleteriously effect on the metallic layers.

### SUMMARY

The disclosed and claimed subject matter is directed to a cleaning composition that contains alpha hydroxy acid and is useful for removing plasma post etch residues from a substrate. The composition comprises:

(i) an alkanolamine having two or more or more than two alkanol groups (R—OH where R is an alkyl group);

(ii) alpha hydroxy acid; and

(iii) water.

In a further embodiment, the composition includes:

(iv) a corrosion inhibitor.

In a further embodiment, the composition consists essentially of (i) an alkanolamine having two or more or more than two alkanol groups (R—OH where R is an alkyl group); (ii) alpha hydroxy acid and (iii) water in varying concentrations. In such an embodiment, the combined amounts of (i), (ii) and (iii) do not equal 100% by weight, and can include other ingredients (e.g., additional solvent(s), common additives and/or impurities) that do not materially change the effectiveness of the composition.

In a further embodiment, the composition consists essentially of (i) an alkanolamine having two or more or more than two alkanol groups (R—OH where R is an alkyl group); (ii) alpha hydroxy acid, (iii) water and (iv) a corrosion inhibitor in varying concentrations. In such an embodiment, the combined amounts of (i), (ii) and (iii) do not equal 100% by weight, and can include other ingredients (e.g., additional solvent(s), common additives and/or impurities) that do not materially change the effectiveness of the composition.

In a further embodiment, the composition consists of (i) an alkanolamine having two or more or more than two alkanol groups (R—OH where R is an alkyl group); (ii) alpha hydroxy acid and (iii) water in varying concentrations. In such an embodiment, the combined amounts of (i), (ii) and (iii) equal approximately 100% by weight but may include other small and/or trace amounts of impurities that are present in such small quantities that they do not materially change the effectiveness of the composition. For example, in one such embodiment, the composition can contain 2% by weight or less of impurities. In another embodiment, the composition can contain 1% by weight or less than of impurities. In a further embodiment, the composition can contain 0.05% by weight or less than of impurities.

In a further embodiment, the composition consists essentially of (i) an alkanolamine having two or more or more than two alkanol groups (R—OH where R is an alkyl group); (ii) alpha hydroxy acid, (iii) water and (iv) a corrosion inhibitor in varying concentrations. In such an embodiment, the combined amounts of (i), (ii), (iii) and (iv) equal approximately 100% by weight but may include other small and/or trace amounts of impurities that are present in such small quantities that they do not materially change the effectiveness of the composition. For example, in one such embodiment, the composition can contain 2% by weight or less of impurities. In another embodiment, the composition can contain 1% by weight or less than of impurities. In a further embodiment, the composition can contain 0.05% by weight or less than of impurities.

In another embodiment, the composition includes (i) between approximately 5% by weight and approximately 50% weight of an alkanolamine having two or more or more than two alkanol groups; (ii) between 25% by weight and approximately 70% by weight of an alkanolamines having one alkanol group; (iii) an alpha hydroxy acid; and (iv) water. In a further aspect, the composition includes (v) catechol. In a further aspect, the composition includes (vi) gallic acid. In a further aspect, the composition includes both of (v) catechol and (vi) gallic acid. In a further aspect, the composition includes (vii) a corrosion inhibitor.

In a further aspect of the composition above, the alkanolamine having two or more or more than two alkanol groups comprises triethanolamine. In a further aspect, the alkanolamine having two or more or more than two alkanol groups consists essentially of triethanolamine. In a further aspect, the alkanolamine having two or more or more than two alkanol groups consists of triethanolamine. In a further aspect, the composition includes between approximately 10% by weight and approximately 40% weight of triethanolamine. In a further aspect, the composition includes between approximately 20% by weight and approximately 30% weight of triethanolamine. In a further aspect, the composition includes approximately 20% by weight of triethanolamine.

In a further aspect of the composition above, the alkanolamine having one alkanol groups comprises monoethanolamine. In a further aspect, the alkanolamine having one alkanol groups consists essentially of monoethanolamine. In a further aspect, the alkanolamine having one alkanol groups consists of monoethanolamine. In a further aspect, the composition includes between approximately 20% by weight and approximately 50% weight of monoethanolamine. In a further aspect, the composition includes between approximately 35% by weight and approximately 50% weight of monoethanolamine. In a further aspect, the composition includes between approximately 35% by weight and approximately 45% weight of monoethanolamine. In a further aspect, the composition includes approximately 35% by weight of monoethanolamine.

In a further aspect of the composition above, the alkanolamine having one alkanol groups comprises 2-(2-aminoethoxy)ethanol. In a further aspect, the alkanolamine having one alkanol groups consists essentially of 2-(2-aminoethoxy)ethanol. In a further aspect, the alkanolamine having one alkanol groups consists of 2-(2-aminoethoxy)ethanol. In a further aspect, the composition includes between approximately 20% by weight and approximately 50% weight of 2-(2-aminoethoxy)ethanol. In a further aspect, the composition includes between approximately 35% by weight and approximately 50% weight of 2-(2-aminoethoxy)ethanol. In a further aspect, the composition includes between approximately 35% by weight and approximately 45% weight of 2-(2-aminoethoxy)ethanol. In a further aspect, the composition includes approximately 35% by weight of 2-(2-aminoethoxy)ethanol.

In a further aspect of the composition above, the alkanolamine having one alkanol groups comprises N-methylethanolamine. In a further aspect, the alkanolamine having one alkanol groups consists essentially of N-methylethanolamine. In a further aspect, the alkanolamine having one alkanol groups consists of N-methylethanolamine. In a further aspect, the composition includes between approximately 20% by weight and approximately 50% weight of N-methylethanolamine. In a further aspect, the composition includes between approximately 35% by weight and approximately 50% weight of N-methylethanolamine. In a further aspect, the composition includes between approximately 35% by weight and approximately 45% weight of N-methylethanolamine. In a further aspect, the composition includes approximately 35% by weight of N-methylethanolamine.

In a further aspect of the composition above, the alkanolamine having one alkanol groups comprises monoisopropylamine. In a further aspect, the alkanolamine having one alkanol groups consists essentially of monoisopropylamine. In a further aspect, the alkanolamine having one alkanol groups consists of monoisopropylamine. In a further aspect, the composition includes between approximately 20% by weight and approximately 50% weight of monoisopropylamine. In a further aspect, the composition includes between approximately 35% by weight and approximately 50% weight of monoisopropylamine. In a further aspect, the composition includes between approximately 35% by weight and approximately 45% weight of monoisopropylamine. In a further aspect, the composition includes approximately 35% by weight of monoisopropylamine.

In a further aspect of the composition above, the alpha hydroxy acid is selected from the group of glycolic acid, lactic acid, tartaric acid, citric acid, malic acid, gluconic acid, glyceric acid, mandelic acid, tartronic acid, saccharic acid and dihydroxymalonic acid and mixtures thereof. In a further aspect, the alpha hydroxy acid consists of gluconic acid. In a further aspect, the composition includes between approximately 2.5% by weight and approximately 25% weight of the alpha hydroxy acid. In a further aspect, the composition includes between approximately 5% by weight and approximately 20% weight of the alpha hydroxy acid. In a further aspect, the composition includes between approximately 10% by weight and approximately 15% weight of the alpha hydroxy acid. In a further aspect, the composition includes approximately 15% weight of the alpha hydroxy acid. In a further aspect, the composition includes approximately 10% weight of the alpha hydroxy acid. In a further aspect, the alpha hydroxy acid comprises gluconic acid. In a further aspect the alpha hydroxy acid consists essentially of gluconic acid. In a further aspect, the composition includes between approximately 2.5% by weight and approximately 25% weight of gluconic acid. In a further aspect, the composition includes between approximately 5% by weight and approximately 20% weight of gluconic acid. In a further aspect, the composition includes between approximately 10% by weight and approximately 15% weight of gluconic acid. In a further aspect, the composition includes approximately 15% weight of gluconic acid. In a further aspect, the composition includes approximately 10% weight of gluconic acid.

In a further aspect of the composition above, the composition includes approximately 10% by weight and approximately 40% by weight of water. In a further aspect, the composition includes between approximately 12% by weight and approximately 35% weight of water. In a further aspect, the composition includes between approximately 13% by weight and approximately 30% weight of water.

In a further aspect of the composition above, the composition includes approximately 6% weight of catechol. In a further aspect, the composition includes approximately 2% weight of gallic acid. In a further aspect, the composition includes approximately 3% weight of gallic acid. In a further aspect, the composition includes between approximately 5% by weight and 10% by weight in combination of catechol and gallic acid. In a further aspect, the composition includes approximately 5% by weight in combination of catechol and gallic acid. In a further aspect, the composition includes approximately 6% by weight in combination of catechol and gallic acid. In a further aspect, the composition includes approximately 7% by weight in combination of catechol and gallic acid. In a further aspect, the composition includes approximately 8% by weight in combination of catechol and gallic acid. In a further aspect, the composition includes approximately 9% by weight in combination of catechol and gallic acid. In a further aspect, the composition includes approximately 9% by weight in combination of catechol and gallic acid.

In another embodiment, the composition includes (i) approximately 20% by weight of triethanolamine and (ii) between approximately 35% by weight and approximately 45% weight of monoethanolamine.

In another embodiment, the composition includes (i) approximately 20% by weight of triethanolamine, (ii) between approximately 35% by weight and approximately 45% weight of monoethanolamine and (iii) approximately 10% weight of gluconic acid.

In another embodiment, the composition includes (i) approximately 20% by weight of triethanolamine, (ii) between approximately 35% by weight and approximately 45% weight of monoethanolamine, (iii) approximately 10% weight of gluconic acid and (iv) approximately 9% by weight in combination of catechol and gallic acid.

In a another embodiment, the above-compositions may have a pH of about 9 or greater, such as, 9-14 or 10-12 or any pH in a range having the beginning and end-points of 9, 10, 11, 12, 13 or 14. Additional basic components may optionally be added to adjust the pH, if needed. In one aspect, components that may be added to adjust the pH include amines, such as primary, secondary, tertiary or quaternary amines, or primary, secondary, tertiary or quaternary ammonium compounds. In another aspect, ammonium salts may alternatively or additionally be included in the compositions. In another aspect, bases that may be added include quaternary ammonium hydroxides in which all of the alkyl groups are the same, such as, tetramethylammonium hydroxide, tetraethylammonium hydroxide, and/or tetrabutylammonium hydroxide and so on. In yet another aspect, the amount of a material added to adjust the pH may be added in a weight percent range having start and end points selected from the following group of numbers: 0, 0.1, 0.2, 0.3, 0.5, 0.8, 1, 2, 3, 4, 5, 6, 7, 8, 9, 10, 11, 12, 14, 15, 17 and 20. Examples of ranges of base, if added to the composition, may be from about 0.1% to about 15% weight percent and, or from about 0.5 to about 10%, or from about from 1 to about 20%, or from about 1 to about 8%, or from about 0.5 to about 5%, or from about 1 to about 7%, or from about 0.5 to about 7% by weight of the composition.

In another embodiment, the compositions may be free or substantially free of any added primary, secondary, tertiary or quaternary amines, and/or primary, secondary, tertiary or quaternary ammonium hydroxides and/or any added ammonium salts in any combination.

The disclosed and claimed subject matter further includes a method of removing residues from a microelectronic device or semiconductor substrate comprising the steps of contacting the substrate containing residues with a cleaning composition of disclosed and claimed subject matter.

This summary section does not specify every embodiment and/or incrementally novel aspect of the disclosed and claimed subject matter. Instead, this summary only provides a preliminary discussion of different embodiments and corresponding points of novelty over conventional techniques and the known art. For additional details and/or possible perspectives of the disclosed and claimed subject matter and embodiments, the reader is directed to the Detailed Description section of the disclosure as further discussed below.

The order of discussion of the different steps described herein has been presented for clarity sake. In general, the steps disclosed herein can be performed in any suitable order. Additionally, although each of the different features, techniques, configurations, etc. disclosed herein may be discussed in different places of this disclosure, it is intended that each of the concepts can be executed independently of each other or in combination with each other as appropriate. Accordingly, the disclosed and claimed subject matter can be embodied and viewed in many different ways.

The section headings used herein are for organizational purposes and are not to be construed as limiting the subject matter described. All documents, or portions of documents, cited in this application, including, but not limited to, patents, patent applications, articles, books, and treatises, are hereby expressly incorporated herein by reference in their entirety for any purpose. In the event that any of the incorporated literature and similar materials defines a term in a manner that contradicts the definition of that term in this application, this application controls.

All references, including publications, patent applications, and patents, cited herein are hereby incorporated by reference to the same extent as if each reference were individually and specifically indicated to be incorporated by reference and were set forth in its entirety herein.

### Definitions

The use of the terms “a” and “an” and “the” and similar referents in the context of describing the disclosed and claimed subject matter (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted, but also include the partially closed or closed terms of “consisting essentially of” and “consisting of.” Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the disclosed and claimed subject matter and does not pose a limitation on the scope of the disclosed and claimed subject matter unless otherwise claimed. No language in the specification should be construed as indicating any non-claimed element as essential to the practice of the disclosed and claimed subject matter. All percentages are weight percentages and all weight percentages are based on the total weight of the composition (prior to any optional concentration and/or dilution thereof). Any reference to “one or more” includes “two or more” and “three or more” and so on.

Preferred embodiments of this disclosed and claimed subject matter are described herein. Variations of those preferred embodiments may become apparent to those of ordinary skill in the art upon reading the foregoing description. The inventors expect skilled artisans to employ such variations as appropriate, and the inventors intend for the disclosed and claimed subject matter to be practiced otherwise than as specifically described herein. Accordingly, this disclosed and claimed subject matter includes all modifications and equivalents of the subject matter recited in the claims appended hereto as permitted by applicable law. Moreover, any combination of the above-described elements in all possible variations thereof is encompassed by the disclosed and claimed subject matter unless otherwise indicated herein or otherwise clearly contradicted by context.

For ease of reference, “microelectronic device” corresponds to semiconductor substrates including wafers, flat panel displays, phase change memory devices, solar panels and other products including solar substrates, photovoltaics, and microelectromechanical systems (MEMS), manufactured for use in microelectronic, integrated circuit, or computer chip applications. Solar substrates include, but are not limited to, silicon, amorphous silicon, polycrystalline silicon, monocrystalline silicon, CdTe, copper indium selenide, copper indium sulfide, and gallium arsenide on gallium. The solar substrates may be doped or undoped. It is to be understood that the term “microelectronic device” is not meant to be limiting in any way and includes any substrate that will eventually become a microelectronic device or microelectronic assembly.

As defined herein, “low-k dielectric material” corresponds to any material used as a dielectric material in a layered microelectronic device, wherein the material has a dielectric constant less than about 3.5. Preferably, the low-k dielectric materials include low-polarity materials such as silicon-containing organic polymers, silicon-containing hybrid organic/inorganic materials, organosilicate glass (OSG), TEOS, fluorinated silicate glass (FSG), silicon dioxide, and carbon-doped oxide (CDO) glass. It is to be appreciated that the low-k dielectric materials may have varying densities and varying porosities.

As defined herein, the term “barrier material” corresponds to any material used in the art to seal the metal lines, e.g., copper interconnects, to minimize the diffusion of said metal, e.g., copper, into the dielectric material. Preferred barrier layer materials include tantalum, titanium, ruthenium, hafnium, and other refractory metals and their nitrides and silicides.

“Substantially free” is defined herein as less than 0.1 wt %, or less than 0.01 wt %, and most preferably less than 0.001 wt % or less than 0.0001 wt %, or less than 1 ppb. “Substantially free” also includes 0.0000 wt % and 0 ppb. The term “free of” means 0.0000 wt % or 0 ppb.

As used herein, “about” or “approximately,” when used in connection with a measurable numerical variable, is intended to correspond to ±5% of the stated value.

In all such compositions, wherein specific components of the composition are discussed in reference to wt % ranges including a zero lower limit, it will be understood that such components may be present or absent in various specific embodiments of the composition, and that in instances where such components are present, they may be present at concentrations as low as 0.001 wt %, based on the total weight of the composition in which such components are employed.

### DETAILED DESCRIPTION

It is to be understood that both the foregoing general description and the following detailed description are illustrative and explanatory, and are not restrictive of the subject matter, as claimed. The objects, features, advantages and ideas of the disclosed subject matter will be apparent to those skilled in the art from the description provided in the specification, and the disclosed subject matter will be readily practicable by those skilled in the art on the basis of the description appearing herein. The description of any “preferred embodiments” and/or the examples which show preferred modes for practicing the disclosed subject matter are included for the purpose of explanation and are not intended to limit the scope of the claims.

It will also be apparent to those skilled in the art that various modifications may be made in how the disclosed subject matter is practiced based on described aspects in the specification without departing from the spirit and scope of the disclosed subject matter disclosed herein.

This disclosed and claimed subject matter provides a composition and method comprising the use of the same for selectively removing residues such as ashed photoresist and/or processing residues from microelectronic devices. In a cleaning method involving articles such as substrates useful for microelectronic devices, typical contaminants to be removed may include, one or more of the following examples, alone or in any combination, organic compounds such as exposed and ashed photoresist material, ashed photoresist residue, UV- or X-ray-hardened photoresist, C—F-containing polymers, low and high molecular weight polymers, and other organic etch residues; inorganic compounds such as metal oxides, ceramic particles from chemical mechanical planarization (CMP) slurries and other inorganic etch residues; metal containing compounds such as organometallic residues and metal organic compounds; ionic and neutral, light and heavy inorganic (metal) species, moisture, and insoluble materials, including particles generated by processing such as planarization and etching processes. In one particular embodiment, residues removed are processing residues such as those created by reactive ion etching.

Moreover, the ashed photoresist and/or processing residues are typically present on a semiconductor substrate (microelectronic device) that also includes one or more of the following materials in any combination: metal (such as copper, aluminum), silicon, silicate and/or interlevel dielectric material such as deposited silicon oxides and derivatized silicon oxides such as HSQ, MSQ, FOX, TEOS and Spin-On Glass, and/or high-k materials, such as hafnium silicate, hafnium oxide, barium strontium titanium (BST), Ta₂O₅, and TiO₂, wherein both the photoresist and/or residues and the metal, silicon, silicide, interlevel dielectric materials and/or high-k materials will come in contact with the cleaning composition. In addition, the composition disclosed herein may exhibit minimal etch rates of certain dielectric materials such as silicon oxide. The composition and method disclosed herein each provides for selectively removing residues without significantly attacking one or more of the following: metal(s), silicon, silicon dioxide, interlevel dielectric materials, and/or high-k materials. In one embodiment, the composition disclosed herein may be suitable for structures containing sensitive low k-films. In certain embodiments, the substrate may contain one or more metals, such as, but not limited to, copper, copper alloy, aluminum, aluminum alloy, titanium, titanium nitride, tantalum, tantalum nitride, tungsten, and titanium/tungsten, one or more of which are not attacked by the cleaning composition.

The compositions of this disclosed and claimed subject matter comprise alkanolamine having at least two R—OH groups, alpha hydroxy acid, water and other optional components.

I. Alkanolamine

The composition comprises at least one alkanolamine having at least two R—OH groups or mixtures of two or more alkanolamines having at least two R—OH groups. The compositions may further comprise one or more additional alkanolamines having one R—OH groups as long as the composition comprises at least one alkanolamine having at least two R—OH groups. The alkanol group is defined as R—OH where R is a straight chained, branched or cyclic alkyl having any number of carbons, but preferably from 1 to 20, or 1 to 15, or 1 to 10, or 1 to 7, or 1 to 5 or 1 to 4 carbons. In some embodiments the alkanolamines useful in the compositions of this disclosed and claimed subject matter having two or more alkanol groups comprise three or more alkanol groups.

Alkanolamines useful in the composition of this disclosed and claimed subject matter are preferably miscible in water.

Examples of alkanolamines useful in this disclosed and claimed subject matter that have more than 1 alkanol group include, but are not limited to, N-methyl diethanolamine, N-ethyl diethanolamine, diethanolamine, triethanolamine (TEA), tertiarybutyldiethanol amine, and mixtures thereof. At least one alkanolamine having more than one alkanol group will be present in the compositions of this disclosed and claimed subject matter. Mixtures of two or more alkanolamines having more than one alkanol group may be used.

Alkanolamines having one alkanol group may be present in the compositions of this disclosed and claimed subject matter. Examples of alkanolamines having one alkanol group that can be used in combination with the alkanolamines having two or more alkanol groups include monoethanolamine (MEA), N-methyl ethanolamine, N-ethyl ethanolamine, N, N-dimethylethanolamine, N, N-diethylethanolamine, isopropanolamine, 2-amino-1-propanol, 3-amino-1-propanol, 2-amino-1-butanol, isobutanolamine, 2-amino-2-ethoxypropanol, 2-amino-2-ethoxyethanol.

In some embodiments, the total amount of alkanolamines (one or two or three or more) may comprise an amount in a range having start and end points selected from the following list of wt % values: 5, 10, 20, 30, 40, 45, 48, 50, 55, 57, 59, 60, 62, 64, 66, 68, 70, 72, 74, 76, 78, 80, 85 and 88. For example, the composition may comprise from about 10% to about 85%, or from about 20% to about 80%, or from about 30% to about 78%, or from about 45% to about 78%, or from about 45% to about 80%, or from about 50% to about 85% by weight of the composition of the one or two or more or three or more of alkanolamines.

In some embodiments comprising two or more alkanolamines (i.e., a first alkanolamine where the first alkanolamine has more than one alkanol group and a second and or third or more alkanolamines that may or may not have more than one alkanol group therein), the first alkanolamine may be present in a wt % equal to or greater than the second alkanolamine, or the first alkanolamine may be present in a wt % that is less than the second alkanolamine. In alternative embodiments, the first alkanolamine may be less than one-third of the total of the alkanolamines in the composition. In alternative embodiments, the second alkanolamine may be less than one-third of the total of the alkanolamines in the composition. Each of the first and second alkanolamines may comprise an amount in a range or ranges independently defined having start and end points selected from the following list of wt % values: 2, 5, 7, 10, 12, 15, 17, 18, 20, 22, 23, 25, 27, 30, 33, 35, 38, 40, 42, 45, 48, 50, 52, 55, 57, 59, 62, 65, 67 and 70. For example, the first alkanolamine or second alkanolamine may be present in amounts independently selected from the following ranges in any combination including both ranges may be the same: from about 2% to about 70%, or from about 2% to about 65%, or from about 2% to about 60%, or from about 2% to about 55%, or from about 2% to about 40%, or from about 5% to about 55%, or from about 7% to about 45%, or from about 5% to about 35%, or from about 20% to about 50%, or from about 15% to about 45%, or from about 35% to about 60%, or from about 15% to about 55%, or from about 25% to about 65%, or from about 10% to about 50%, or from about 7% to about 52% by weight of the composition.

In some embodiments, an optional third and/or fourth or more (each of which may or may not have one or more than one alkanol groups) alkanolamine may be present in the compositions of this disclosed and claimed subject matter. The composition may comprise an amount of the third alkanolamine in a range having start and end points selected from the following list of wt % values: 0, 0.5, 1, 1.5, 2, 5, 7, 10, 12, 15, 17, 18, 20, 22, 23, 25, 27, 30, 33, 35, 38, and 40. For example, the composition may comprise from about 0% to about 40%, or from about 0.5% to about 40%, or from about 0.5% to about 20%, or from about 0.5% to about 15%, or from about 1% to about 10%, or from about 1% to about 7% by weight of the composition of the third alkanolamine. The fourth alkanolamine if present may be present in a range having start and end points selected from the following list of wt % values: 0, 0.5, 1, 1.5, 2, 5, 7, 10, 12, 15, 17, 18, 20, 22, 23, 25, 27, 30, 33, 35, 38, and 40. For example, the composition may comprise from about 0% to about 40%, or from about 0.5% to about 40%, or from about 0.5% to about 20%, or from about 0.5% to about 15%, or from about 1% to about 10%, or from about 1% to about 7% by weight of the composition of the fourth alkanolamine.

The two or more alkanolamines (other than the first alkanolamine) may comprise alkanolamines having one or more than one alkanol groups and/or ether groups or other groups therein in any combination. In some embodiments, the second alkanolamine may comprises alkanolamines having one alkanol group therein. In other embodiments, the first and second alkanolamines may comprise alkanolamines having more than one alkanol groups or the first alkanolamine may comprise more than two alkanol groups therein and the second alkanolamine may comprise one or more than one alkanol groups therein. In yet other embodiments comprising a third alkanolamine, the third alkanolamine may comprise an alkanolamine having one or more alkanol groups and/or the third alkanolamine may comprise an alkanolamine having an ether group therein.

Examples of alkanolamines with one alkanol group therein include monoethanolamine (MEA), methanolamine, N-methyl ethanolamine, N-ethyl ethanolamine, N, N-dimethylethanolamine, N, N-diethylethanolamine, isopropanolamine, 2-amino-1-propanol, 3-amino-1-propanol, 2-amino-1-butanol, isobutanolamine, 2-amino-2-ethoxypropanol and 2-amino-2-ethoxyethanol. 2-amino-2-ethoxypropanol and 2-amino-2-ethoxyethanol have a single alkanol group, and also have an ether group.

Examples of alkanolamines with more than one alkanol group therein include N-methyl diethanolamine, N-ethyl diethanolamine, diethanolamine, triethanol amine (TEA), and tertiarybutyldiethanol amine.

Examples of alkanolamines with more than two alkanol group therein include triethanol amine (TEA).

Examples of an alkanolamine comprising an ether include aminoethoxy ethanol (AEE), 2-amino-2-ethoxypropanol and 2-amino-2-ethoxyethanol.

II. α-Hydroxy Carboxylic Acid

The compositions of this disclosed and claimed subject matter comprise one or more α-hydroxy carboxylic acids (a.k.a. alpha-hydroxy carboxylic acids and/or alpha-hydroxy acids). The α-hydroxy carboxylic acids may comprise more than one acid group (—COOH). α-Hydroxy carboxylic acids may have the following structure:

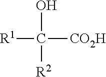

(designated herein as “R¹-R²C(OH)—COOH”), where R¹ and R² can independently be H, an aromatic or non-aromatic and/or saturated or unsaturated carbon ring; or a straight-chain, branched or cyclic alkyl. The rings may be heterocyclic or may be substituted thereon with groups containing heteroatoms, and the alkyl groups (for example, C₁-C₁₀) may also contain therein or be substituted thereon with groups containing heteroatoms; or there may be no heteroatoms in or on R¹ and/or R². Often, R¹ is an alkyl group having one or more additional —OH groups substituted thereon, and R² is H. R¹ and/or R² may also be or contain one or more additional acid groups, for the α-hydroxy carboxylic acids having more than one acid groups, such as citric acid, tartronic acid, saccharic acid, tartaric acid and dihydroxymalonic acid. In alternate embodiments, R¹ and R² may be combined to form an aromatic or non-aromatic and/or saturated or unsaturated carbon ring; or a straight-chain, branched or cyclic alkyl group.

Examples of α-hydroxy carboxylic acids useful in the compositions of this disclosed and claimed subject matter include glycolic acid, lactic acid, tartaric acid, citric acid, malic acid, gluconic acid, glyceric acid, mandelic acid, tartronic acid, saccharic acid and dihydroxymalonic acid and mixtures thereof. The compositions of this disclosed and claimed subject matter may comprise one or more α-hydroxy carboxylic acids in an amount in a range having start and end points selected from the following list of wt % values: 0.5, 1, 2, 3, 4, 5, 7, 10, 12, 14, 15, 17, 18, 20, 22, 25, 27, 30, 33, 35, 38 and 40, for example, from about 0.5% to about 40% by weight, or from about 1% to about 35% by weight, or from about 2% to about 30% by weight, or from about 3% to about 27% by weight, or from about 4% to about 25% by weight, or from about 5% to about 30% by weight of α-hydroxy carboxylic acids (neat).

III. Water

The cleaning compositions of the present disclosed and claimed subject matter are aqueous-based and thus comprise water. In the present disclosed and claimed subject matter, water functions in various ways, such as, to dissolve one or more solid components of the residue, as a carrier of the components, as an aid in the removal of metallic residue, as a viscosity modifier of the composition, and as a diluent. Preferably, the water employed in the cleaning composition is de-ionized (DI) water.

It is believed that, for most applications, water may comprise an amount in a range having start and end points selected from the following list of wt % values: 5, 10, 13, 15, 17, 18, 20, 22, 25, 27, 30, 33, 35, 38, 40, 42, 45 and 50, for example, from about 5% to about 50% by weight, or from about 10% to about 40% by weight, or about 10% to about 30% by weight, or from about 5% to about 30% by weight, or from about 5% to about 25% by weight, or from about 10% to about 25% by weight of water. Still other preferred embodiments of the present disclosed and claimed subject matter could include water in an amount to achieve the desired wt % of the other ingredients.

IV. Optional Corrosion Inhibitor

The compositions of the present disclosed and claimed subject matter optionally comprise one or more than one corrosion inhibitors. The corrosion inhibitors useful in this disclosed and claimed subject matter may be phenol, derivatives of phenol or mixtures thereof. The phenolic derivatives as corrosion inhibitors useful in this disclosed and claimed subject matter include catechol, t-butyl catechol, resorcinol, pyrogallol, p-benzenediol, m-benzenediol, o-benzenediol, 1,2,3-benzenetriol, 1,2,4-benzenetriol, and 1,3,5-benzenetriol, gallic acid, and derivatives of gallic acid, cresol, xylenol, salicyl alcohol, p-hydroxybenzyl alcohol, o-hydroxybenzyl alcohol, p-hydroxyphenethyl alcohol, p-aminophenol, m-aminophenol, diaminophenol, p-hydroxybenzoic acid, o-hydroxybenzoic acid, 2,4-dihydroxybenzoic acid, 2-5-dihydroxybenzoic acid, 3,4 dihydroxybenzoic acid and 3,5-dihydroxybenzoic acid or mixtures thereof. The phenolic derivative compound(s) useful in this disclosed and claimed subject matter may have at least two hydroxyl groups. As noted, the phenolic derivatives as corrosion inhibitors useful in this disclosed and claimed subject matter may be gallic acid, and derivatives of gallic acid and mixtures thereof. The derivatives of gallic acid include methyl gallate, phenyl gallate, 3,4,5 triacetoxygallic acid, trimethyl gallic acid methyl ester, ethyl gallate, and gallic acid anhydride and mixtures thereof.

The corrosion-inhibitors may be triazole compounds, alone or in combination with other corrosion inhibitors including the phenol and derivatives of phenol corrosion inhibitors. Exemplary triazole compounds include benzotriazole, o-tolyltriazole, m-tolyltriazole, p-tolyltriazole, carboxybenzotriazole, 1-hydroxybenzotriazole, nitrobenzotriazole and dihydroxypropylbenzotriazole and mixtures thereof. In some other embodiments, the corrosion inhibitor is a triazole and is at least one of benzotriazole, o-tolyltriazole, m-tolyltriazole, and p-tolyltriazole and mixtures thereof.

Alternative corrosion inhibitors that may be used in the composition of this disclosed and claimed subject matter comprise at least one polyfunctional organic acid that are not α-hydroxy acids, alone or in combination with one or more other corrosion inhibitors. As used herein, the term “polyfunctional organic acid” refers to an acid or a multi-acid that has more than one carboxylate group, including but not limited to, (i) dicarboxylate acids (such as oxalic acid, malonic acid, malic acid, tartaric acid, succinic acid et al.); dicarboxylic acids with aromatic moieties (such as phthalic acid et al.), methyliminodiacetic acid, nitrolotriacetic acid (NTA) and combinations thereof; (ii) tricarboxylic acids (such as propane-1,2,3-tricarboxylic acid, et al.), (hydroxyethyl)ethylenediaminetriacetic acid (HEDTA), tricarboxylic acids with aromatic moieties (such as trimellitic acid, et al.), and combinations thereof; and (iii) tetracarboxylic acid such as, for example, ethylenediaminetetraacetic acid (EDTA), butylenediaminetetraacetic acid, (1,2-cyclohexylenedinitrilo-)tetraacetic acid (CyDTA), ethylenediaminetetrapropionic acid, N, N,N′,N′-ethylenediaminetetra(methylenephosphonic) acid (EDTMP), 1,3-diamino-2-hydroxypropane-N,N,N′,N′-tetraacetic acid (DHPTA), propylenediaminetetraacetic acid, and combinations thereof (iv) and others including diethylenetriaminepentaacetic acid (DETPA) and triethylenetetraminehexaacetic acid (TTHA) and combinations thereof. It is believed that the polyfunctional organic acid component primarily functions as a metal corrosion inhibitor and/or a chelating agent.

Preferred polyfunctional organic acids include, for example, those that have at least three carboxylic acid groups. Polyfunctional organic acids having at least three carboxylic acid groups are highly miscible with water. Examples of such acids include tricarboxylic acids (e.g., 2-methylpropane-1,2,3-triscarboxylic, benzene-1,2,3-tricarboxylic [hemimellitic], propane-1,2,3-tricarboxylic [tricarballylic], 1,cis-2,3-propenetricarboxylic acid [aconitic], and the like), tetracarboxylic acids (e.g., butane-1,2,3,4-tetracarboxylic, cyclopentanetetra-1,2,3,4-carboxylic, benzene-1,2,4,5-tetracarboxylic [pyromellitic], and the like), pentacarboxlyic acids (e.g., benzenepentacarboxylic), and hexacarboxylic acids (e.g., benzenehexacarboxylic [mellitic]), ethylenediaminetetraacetic acid (EDTA) and the like.

Another type of corrosion inhibitor that may be used in the compositions of this disclosed and claimed subject matter, alone or in addition to one or more of the other corrosion inhibitors include amino acids. Examples of amino acids useful in the composition of this disclosed and claimed subject matter include glycine, histidine, lysine, alanine, leucine, threonine, serine, valine, aspartic acid, glutamic acid, arginine. Still other amino acids that may be used in the compositions of this disclosed and claimed subject matter include cysteine, asparagine, glutamine, isoleucine, methionine, phenylalanine, proline, tryptophan, and tyrosine. Some preferred amino acids include glycine, alanine, valine, leucine, isoleucine, histidine. Mixtures of amino acids may also be used.

It is believed that the total amount of the one or more corrosion inhibitors in the cleaning composition of the present disclosed and claimed subject matter may be in a range having start and end points selected from the following list of weight wt % values: 0, 0.1, 0.2, 0.5, 1, 1.5, 2, 3, 4, 5, 6, 7, 8, 10, 12, 15, 20, for example, from about 0.1% to about 15%, or from about 0.1% to about 10%, or from about 0.1% to about 8%, or from about 0.5% to about 15%, or from about 0.5% to about 10%, or from about 1% to about 12%, or from about 1% to about 10%, or from about 1% to about 8% by weight of the composition.

In some embodiments the compositions of this disclosed and claimed subject matter will be free of or substantially free of any or all of the above-listed additional types of corrosion inhibitors or any one or more of the individual corrosion inhibitors, in any combination, added to the composition.

V. Other Optional Ingredients

A. Additional Organic Acids

The compositions of this disclosed and claimed subject matter may comprise additional organic acids (different from the types of α-hydroxy carboxylic acids listed above), including hydroxybutyric acid, hydroxypentanoic acid, formic acid, oxalic acid, malonic acid, ascorbic acid, succinic acid, glutaric acid maleic acid, and salicylic acid. Alternatively, the compositions of this disclosed and claimed subject matter may be substantially free of, or free of, any or all additional organic acids listed above in any combination, or substantially free of, or free of all additional organic acids. For example, the compositions of this disclosed and claimed subject matter may be substantially free of, or free of formic acid or malonic acid or the compositions of this disclosed and claimed subject matter may be substantially free of, or free of formic acid, glutaric acid and malonic acid. If present, the additional organic acids may be present from about 0.1 to 10% by weight.

B. Water-Miscible Solvent

The etching compositions of the present disclosed and claimed subject matter may comprise a water-miscible solvent. Examples of water-miscible organic solvents that can be employed are N-methylpyrrolidone (NMP), 1-methoxy-2-propyl acetate (PGMEA), ethylene glycol, propylene glycol, butyl diglycol, 1,4-butanediol, tripropylene glycol methyl ether, propylene glycol propyl ether, diethylene gycol n-butyl ether (e.g., commercially available under the trade designation Dowanol DB®), hexyloxypropylamine, poly(oxyethylene)diamine, dimethylsulfoxide, tetrahydrofurfuryl alcohol, glycerol, alcohols, sulfoxides, or mixtures thereof. Preferred solvents are alcohols, diols, or mixtures thereof.

In some embodiments of the present disclosed and claimed subject matter, the water-miscible organic solvent may comprise a glycol ether. Examples of glycol ethers include ethylene glycol monomethyl ether, ethylene glycol monoethyl ether, ethylene glycol monobutyl ether, ethylene glycol dimethyl ether, ethylene glycol diethyl ether, diethylene glycol monomethyl ether, diethylene glycol monoethyl ether, diethylene glycol monopropyl ether, diethylene glycol monoisopropyl ether, diethylene glycol monobutyl ether, diethylene glycol monoisobutyl either, diethylene glycol monobenzyl ether, diethylene glycol dimethyl ether, diethylene glycol diethyl ether, triethylene glycol monomethyl ether, triethylene glycol dimethyl ether, polyethylene glycol monomethyl ether, diethylene glycol methyl ethyl ether, triethylene glycol ethylene glycol monomethyl ether acetate, ethylene glycol monethyl ether acetate, propylene glycol methyl ether acetate, propylene glycol monomethyl ether, propylene glycol dimethyl ether, propylene glycol monobutyl ether, propylene glycol, monopropyl ether, dipropylene glycol monomethyl ether, dipropylene glycol monopropyl ether, dipropylene glycol monoisopropyl ether, dipropylene monobutyl ether, diproplylene glycol diisopropyl ether, tripropylene glycol monomethyl ether, 1-methoxy-2-butanol, 2-methoxy-1-butanol, 2-methoxy-2-methylbutanol, 1,1-dimethoxyethane and 2-(2-butoxyethoxy) ethanol.

It is believed that, for most applications, the amount of water-miscible organic solvent in the composition may be in a range having start and end points selected from the following list of wt % values: 0, 0.1, 0.5, 1, 5, 7, 12, 15, 20, 25, 30, 50, 65 and 70. Examples of such ranges of solvent include from about 0.5% to about 80% by weight; or from about 0.5% to about 65% by weight; or from about 1% to about 50% by weight; or from about 0.1% to about 30% by weight 0.5% to about 25% by weight; or from about 0.5% to about 15% by weight; or from about 1% to about 7% by weight; or from about 0.1% to about 12% by weight of the composition.

The solvents, if present, may support the cleaning action and protect the wafer surfaces.

In some embodiments the compositions of this disclosed and claimed subject matter will be free of, or substantially free of, any or all of the above-listed water-miscible organic solvents in any combination, or all water-miscible organic solvents added to the composition.

C. Other Optional Ingredients

In other embodiments, the compositions may comprise or be substantially free of or free of any or all of hydroxylamine, oxidizer, surfactants, chemical modifiers, dyes, biocides, chelating agents, corrosion inhibitors, added acids, and/or added bases.

Some embodiments may comprise hydroxyquinoline or be free or substantially free of hydroxyquinoline.

In some embodiments, the compositions of this disclosed and claimed subject matter may be free of or substantially free of at least one or more than one in any combination, or all of the following, or free of any additional of the following if already present in the composition: sulfur-containing compounds, bromine-containing compounds, chlorine-containing compounds, iodine-containing compounds, fluorine-containing compounds, halogen-containing compounds, phosphorus-containing compounds, metal-containing compounds, hydroxylamine or derivatives of hydroxylamine, including N,N-diethyl hydroxylamine (DEHA), isopropylhydroxylamine, or salts of hydroxylamine, such as hydroxylammonium chloride, hydroxylammonium sulfate, sodium-containing compounds, calcium-containing compounds, alkyl thiols, organic silanes, halide-containing compound, oxidizing agents, peroxides, buffer species, polymers, inorganic acids, amides, metal hydroxides, ammonium hydroxides, quaternary ammonium hydroxides and strong bases.

Composition pH

The compositions of this disclosed and claimed subject matter may have a pH of about 9 or greater, such as, 9-14 or 10-12 or any pH in a range having the beginning and end-points of 9, 10, 11, 12, 13 or 14. Additional basic components may optionally be added to adjust the pH, if needed. Examples of components that may be added to adjust the pH include amines, such as primary, secondary, tertiary or quaternary amines, or primary, secondary, tertiary or quaternary ammonium compounds. Alternatively or additionally, ammonium salts may be included in the compositions.

Examples of bases that may be added include quaternary ammonium hydroxides in which all of the alkyl groups are the same, such as, tetramethylammonium hydroxide, tetraethylammonium hydroxide, and/or tetrabutylammonium hydroxide and so on.

It is believed that if a base is added, it is added in an amount to provide the desired pH. The amount added may be in a weight percent range having start and end points selected from the following group of numbers: 0, 0.1, 0.2, 0.3, 0.5, 0.8, 1, 2, 3, 4, 5, 6, 7, 8, 9, 10, 11, 12, 14, 15, 17 and 20. Examples of ranges of base, if added to the composition of this disclosed and claimed subject matter, may be from about 0.1% to about 15% weight percent and, or from about 0.5 to about 10%, or from about from 1 to about 20%, or from about 1 to about 8%, or from about 0.5 to about 5%, or from about 1 to about 7%, or from about 0.5 to about 7% by weight of the composition.

In alternative embodiments the compositions may be free or substantially free of any added primary, secondary, tertiary or quaternary amines, and/or primary, secondary, tertiary or quaternary ammonium hydroxides and/or any added ammonium salts in any combination.

Methods of Use

The method described herein may be conducted by exposing or otherwise contacting (e.g., dipping or spraying one at a time or with a plurality of substrates into a bath that is sized to receive the plurality of substrates) a substrate having an organic or metal-organic polymer, inorganic salt, oxide, hydroxide, or complex or combination thereof present as a film or residue with the described composition. The actual conditions, e.g., temperature, time, etc. depend on the nature and the thickness of the material to be removed.

In general, the substrate is contacted or dipped into a vessel containing the cleaning composition of this disclosed and claimed subject matter at a temperature ranging from about 20° C. to about 90° C., or from about 20° C. to about 80° C., or from about 40° C. to about 80° C. Typical time periods for exposure of the substrate to the composition may range from, for example, 0.1 to 90 minutes, or 1 to 60 minutes, or 1 to 30 minutes. After contact with the composition, the substrate may be rinsed and then dried. Drying is typically carried out under an inert atmosphere and may include spinning. In certain embodiments, a deionized water rinse or rinse containing deionized water with other additives may be employed before, during, and/or after contacting the substrate with the composition described herein.

Materials removed with the compositions described herein include ashed photoresists and processing residues known in the art by such names as sidewall polymers, veils, fences etch residue, ash residue and the like. In certain preferred embodiments, the photoresist is exposed, developed, etched and ashed prior to contact with the composition described herein. The compositions disclosed herein typically are compatible with low-k films such as HSQ (FOx), MSQ, SiLK, etc. The formulations may be effective in stripping ashed photoresists including positive and negative photoresists and plasma etch residues such as organic residues, organometallic residues, inorganic residues, metallic oxides, or photoresist complexes at low temperatures with very low corrosion of tungsten, aluminum, copper, titanium containing substrates. Moreover, the compositions are also compatible with a variety of high dielectric constant materials. For many of the listed metals, for example for aluminum, copper, or aluminum and copper alloys, or tungsten, etc., the etch rates provided by the compositions and methods of this disclosed and claimed subject matter may be less than about 5 Å/min, or less than about 4 Å/min, or less than about 3 Å/min, or less than about 2 Å/min, or less than about 1.5 Å/min, or less than about 1 Å/min, which may be provided at processing temperatures of less 90° C.

### Examples

Reference will now be made to more specific embodiments of the present disclosure and experimental results that provide support for such embodiments. The examples are given below to more fully illustrate the disclosed subject matter and should not be construed as limiting the disclosed subject matter in any way.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

In all tables, all amounts are given in weight percent and add up to 100 weight percent. The compositions disclosed herein were prepared by mixing the components together in a vessel at room temperature until all solids have dissolved.

Materials and Methods

The materials used in the various formulations described include ingredients that are commercially available and were used without further purifying unless otherwise noted.

Etch rate (“ER”) measurements were conducted at 20 minutes of exposure at 70° C. or 75° C. In determining the aluminum (contains 2% Cu) and titanium etch rates, the wafers had a blanker layer of a known thickness deposited upon it. The initial thickness of the wafer was determined using the CDE ResMap 273 Four Point Probe. After determining the initial thickness, test wafers were immersed in the exemplary compositions. After 20 minutes, the test wafers were removed from the test solution, rinsed with N-methyl-2-pyrrolidone solvent first and then rinsed for three minutes with deionized water and completely dried under nitrogen. The thickness of each wafer was measured, and if necessary, the procedure was repeated on the test wafer. The etch rates were then obtained from the thickness change divided by the processing time.

The cleaning tests were carried out on patterned wafers. Some cleaning tests were carried on three kinds of patterned wafers: (i) 400 nm AlCu metal line with SiON, (ii) 4 μm AlCu metal line and (iii) Ti-containing vias for evaluating cleaning performance of different solutions. The substrates were immersed into the solutions with stirring of 400 rpm at 60° C., 20 minutes for all substrates. Some cleaning tests were carried out on two kinds of patterned wafers: (i) 400 nm AlCu metal lines, (ii) 4 μm AlCu metal pads. The substrates were immersed into the solutions with stirring of 400 rpm at 75° C., 10 minutes for 400 nm AlCu metal lines and 30 minutes for 4 μm AlCu metal pads. After exposure to the exemplary composition, the wafer(s) were rinsed with deionized water and dried with nitrogen gas. The wafers were cleaved to provide an edge then examined using a Hitachi SU-8010 scanning electron microscopy (SEM) on a variety of pre-determined locations on the wafer and the results were visually interpreted.

Table 1 shows that the addition of gluconic acid into alkanolamine solution containing trietchanolamine resulted in a decrease in AlCu etch rates and those formulations could clean the post etch residues on the pattern wafers without etching AlCu metal substrates.

TABLE 1
Effect of Gluconic Acid on AlCu Eetch Rates and
Cleaning Performance

| | Exp. | Exp. | Exp. | Exp. | Exp. | Exp. |
|---|---|---|---|---|---|---|
| | 1 | 2 | 3 | 4 | 5 | 6 |
| Monoethanolamine | 55 | 50 | — | 44 | 48.5 | 51.7 |
| Triethanolamine | 25 | — | 50 | 20 | 22.0 | 23.5 |
| Gluconic Acid | — | 25 | 25 | 10 | 22 | 23.5 |
| Water | 25 | 25 | 25 | 26 | 18.5 | 13 |
| AlCu ER (Å/min) | >50 | 4.7 | 0.3 | 3.1 | 1.2 | 0 |
| (20 min. at 75° C. | | | | | | |
| Cleaning on | Complete | Cleaned | Partially | Clean | Clean | Clean |
| 400 nm AlCu Line | etched | | clean | | | |
| (10 min. at 75° C.) | | | | | | |
| Cleaning on 4 μm | Clean, | Cleaned | Partially | Clean | Clean | Clean |
| AlCu Pad | etched | | cleaned | | | |
| (30 min. at 75° C.) | | | | | | |

Table 2 shows that different alkanolamines, other than MEA, had an effect on AlCu etch rates. The addition of catechol and gallic acid in the formulations increased AlCu etch rates. The addition of catechol had greater effect than gallic acid and showed increased AlCu etch on pattern wafers.

TABLE 2
Effect of Different Alkanolamines on AlCu Etch Rates and Cleaning Performance

| | Exp. | Exp. | Exp. | Exp. | Exp. | Exp. | Exp. | Exp. |
|---|---|---|---|---|---|---|---|---|
| | 7 | 8 | 9 | 10 | 11 | 12 | 13 | 14 |
| Monoethanolamine | 69 | 49 | — | 43 | 47 | — | — | 55 |
| 2-(2-Aminoethoxy)ethanol | — | — | 49 | — | — | — | — | — |
| N-Methylethanolamine | — | — | — | — | — | 49 | — | — |
| Monoisopropylamine | — | — | — | — | — | — | 49 | — |
| Triethanolamine | 30 | 10 | 10 | 10 | 10 | 10 | 10 | 10 |
| Gluconic Acid | 5 | 15 | 15 | 15 | 15 | 15 | 15 | 15 |
| Catechol | — | — | — | 6 | — | — | — | — |
| Gallic Acid | — | — | — | — | 2 | — | — | — |
| Water | 26 | 26 | 26 | 26 | 26 | 26 | 26 | 20 |
| AlCu ER (Å/min) | 6.7 | 2.8 | 1.8 | 20.8 | 4.2 | 4.3 | 1.6 | 1.1 |
| (75° C. at 20 min.) | | | | | | | | |
| Cleaning on 400 nm AlCu | Clean, | Clean | Clean | Clean, | Clean | Clean | Clean | Clean |
| Line (10 min. at 75° C.) | slight | | | etched | | | | |
| | etched | | | | | | | |
| Cleaning on 4 μm AlCu Pad | Clean | Clean | Clean | Clean, | Clean | Clean | Clean | Clean |
| (30 min. at 75° C.) | | | | etched | | | | |

Table 3 shows the effects of adding citric acid in the formulations on the AlCu etch rates and cleaning performance. As demonstrated, the addition of citric acid could lower AlCu etch rates without an effect on cleaning performance.

TABLE 3
Effect of Citric Acid Addition on AlCu Etch Rates and
Cleaning Performance

| | Exp. | Exp. | Exp. | Exp. | Exp. | Exp. | Exp. |
|---|---|---|---|---|---|---|---|
| | 15 | 16 | 17 | 18 | 19 | 20 | 21 |
| Monoethanolamine | 24 | 24 | 24 | 26.5 | 34 | 34 | 34 |
| 2-(2-Aminoethoxy) | — | — | — | 10 | 10 | 10 | 20 |
| ethanol | | | | | | | |
| Triethanolamine | 40 | 28 | 28 | 15 | 10 | 15 | 5 |
| Gluconic Acid | 10 | 10 | 5 | 10 | 10 | 5 | 5 |
| Catechol | — | 6 | 6 | — | — | — | — |
| Gallic Acid | — | 2 | 2 | — | — | — | — |
| Citric Acid | — | 4 | 4 | 5 | 10 | 10 | 10 |
| Water | 26 | 26 | 26 | 26 | 26 | 26 | 26 |
| AlCu ER (Å/min) | 3.3 | 13.0 | 8.0 | 2.6 | 3.9 | 2.2 | 2.7 |
| at 75° C. | | | | | | | |
| Cleaning on 400 nm | Clean | Clean | Clean | Clean | Clean | Clean | Clean |
| AlCu Line | | | | | | | |
| (10 min. at 75° C.) | | | | | | | |
| Cleaning on 4 μm | Clean | Clean | Clean | Clean | Clean | Clean | Clean |
| AlCu Pad | | | | | | | |
| (30 min. at 75° C.) | | | | | | | |

Table 4 shows that formulations containing lactic acid had higher Alcu etch rates than those formulations containing gluconic acid. The addition of citric acid decreased AlCu etch rates in these formulations. These formulations could clean the post etch residues on the patterned wafers.

TABLE 4
Cleaning Performance of Formulations Containing Lactic Acid

| | Exp. | Exp. | Exp. | Exp. | Exp. | Exp. |
|---|---|---|---|---|---|---|
| | 22 | 23 | 24 | 25 | 26 | 27 |
| Monoethanolamine | 35 | 35 | 30 | 30 | 32 | 22 |
| Triethanolamine | 20 | 17.5 | 20 | 17.5 | 10 | 20 |
| 2-(2-Aminoethoxy)ethanol | 10 | 10 | 6 | 6 | 10 | 10 |
| Catechol | — | — | 6 | 6 | — | — |
| Gallic Acid | — | — | 3 | 3 | — | — |
| Lactic Acid | 8.5 | 8.5 | 8.5 | 8.5 | 17.5 | 17.5 |
| Citric Acid | | 2.5 | | 2.5 | 2 | 2 |
| Water | 25 | 25 | 25 | 25 | 27.5 | 28.5 |
| AlCu ER at 75° C. | 23.3 | 10.4 | 14.4 | 12.9 | 20.3 | 19.2 |
| Cleaning on 400 nm AlCu | Clean, | Clean | Clean | Clean | — | — |
| Line (10 min. at 75° C.) | etched | | | | | |
| Cleaning on 4 μm AlCu | Clean, | Clean | Clean | Clean | — | — |
| Pad (30 min. at 75° C.) | slight | | | | | |
| | etched | | | | | |

Table 5 demonstrates that the addition of gluconic acid to formulations including triethanolamine and monoethanolamine causes the Ti etch rates to increase. Further, it was also demonstrated that the addition of triammonium citrate in the formulations decreased Ti etch rates.

TABLE 5
AlCu and Ti Etch Rates at 70° C.

| | Exp. | Exp. | Exp. | Exp. | Exp. | Exp. | Exp. | Exp. | Exp. | Exp. |
|---|---|---|---|---|---|---|---|---|---|---|
| | 28 | 29 | 30 | 31 | 32 | 33 | 34 | 35 | 36 | 37 |
| Monoethanolamine | 72 | 45 | 45 | 44 | 25 | 25 | 25 | 44 | 39 | 39 |
| Triethanolamine | — | 20 | 20 | 20 | 40 | 40 | 40 | 20 | 20 | 20 |
| 2-(2-Aminoethoxy)ethanol | — | 6 | 4 | — | 6 | 4 | — | — | — | — |
| Gluconic Acid | — | 2.5 | 5 | 10 | 2.5 | 5 | 9.5 | 7.5 | 10 | 7.5 |
| Triammonium | — | — | — | — | — | — | — | 5 | 5 | 10 |
| Citrate | | | | | | | | | | |
| Water | 28 | 26.5 | 26 | 26 | 26.5 | 26 | 25.5 | 23.5 | 26 | 23.5 |
| pH at 5% solution | — | 11.2 | 10.9 | 10.7 | 11.2 | 11.0 | 10.7 | 10.3 | 10.6 | 10.3 |
| AlCu ER | >50 | 7.4 | 1.45 | 1.40 | 1.8 | 6.0 | 0.25 | 2.18 | 2.4 | 2.6 |
| (70° C. 20 min, Å/min) | | | | | | | | | | |
| Ti ER | 0.02 | 0.4 | 0.5 | 0.55 | 0.3 | 0.25 | 0.9 | 0.05 | 0.42 | 0.05 |
| (70° C. 20 min, Å/min) | | | | | | | | | | |

Table 6 demonstrates that the addition of gallic acid or catechol in the formulations containing gluconic acid decreased Ti etch rates. The variation of traiammonium citrate and gluconic acid concentration is also demonstrated to have an effect on AlCu etch rates.

TABLE 6
AlCu and Ti Etch Rates of Examples

| | Exp. | Exp. | Exp. | Exp. | Exp. | Exp. | Exp. | Exp. | Exp. |
|---|---|---|---|---|---|---|---|---|---|
| | 38 | 39 | 40 | 41 | 42 | 43 | 44 | 45 | 46 |
| Monoethanolamine | 41 | 35 | 38 | 38 | 35 | 28 | 54 | 44 | 48 |
| Triethanolamine | 20 | 20 | 20 | 20 | 20 | 30 | 10 | 10 | 10 |
| Catechol | — | 6 | 6 | — | 3 | — | — | — | — |
| Gallic Acid | 3 | 3 | — | 6 | 6 | 6 | — | — | 6 |
| Gluconic Acid | 10 | 10 | 10 | 10 | 10 | 10 | 10 | 20 | 10 |
| Water | 26 | 26 | 26 | 26 | 26 | 26 | 26 | 26 | 26 |
| pH at 5% solution | 10.7 | 10.5 | 10.6 | — | — | — | 11.05 | 10.76 | 10.57 |
| AlCu ER | 0.65 | 2.0 | 5.8 | 6.5 | 6.8 | 8.4 | 14.1 | 8.0 | 8.1 |
| (70° C. 20 min, Å/min) | | | | | | | | | |
| Ti ER | −0.3 | −0.2 | 0.1 | 0.18 | −0.43 | 0.5 | 0.12 | 0.25 | 0.15 |
| (70° C. 20 min, Å/min) | | | | | | | | | |

Table 7 provides a summary of cleaning test performed at 60° C. for 20 minutes on different substrates. As shown in Table 7, all the formulations had good cleaning on Ti-containing vias which Ti-containing residues were deposited on the sidewalls. In addition, depending on formulation, ALCu metal line substrates could be cleaned without AlCu corrosion.

TABLE 7
Cleaning Performance on Patterned Wafers at 60° C.

| | Substrate and Cleaning Result | | |
|---|---|---|---|
| | AlCu line/SiON | AlCu Thick line | Ti-containing |
| Formulation | (400 nm thick) | (4 μm thick) | Via |
| Exp. 1 | Some residue | — | Clean |
| Exp. 2 | Some residue | — | Clean |
| Exp. 3 | Some residue | — | Clean |
| Exp. 15 | Slight residue | Clean | Clean |
| Exp. 38 | Clean | Clean | Clean |
| Exp. 39 | Clean | Clean | Clean |
| Exp. 40 | Clean but Al | Clean | Clean |
| | line etched | | |
| Exp. 35 | Some residue | Slight residue | Clean |
| Exp. 36 | Some residue | Slight residue | Clean |
| Exp. 37 | Some residue | Slight residue | Clean |

Although the disclosed and claimed subject matter has been described and illustrated with a certain degree of particularity, it is understood that the disclosure has been made only by way of example, and that numerous changes in the conditions and order of steps can be resorted to by those skilled in the art without departing from the spirit and scope of the disclosed and claimed subject matter.

1-39. (canceled)

40. A cleaning composition for semiconductor substrates comprising:
(i) between approximately 5% by weight and approximately 50% weight of an alkanolamine having two or more or more than two alkanol groups;
(ii) between 25% by weight and approximately 70% by weight of an alkanolamine having one alkanol group;
(iii) an alpha hydroxy acid having the following structure 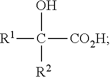
and
(iv) water.

41. (canceled)

42. (canceled)

43. The composition of claim 40, further comprising one or both of (v) catechol and (vi) gallic acid.

44. The composition of claim 40, further comprising (vii) a corrosion inhibitor.

45. The composition of claim 40, wherein the alkanolamine having two or more or more than two alkanol groups comprises triethanolamine.

46. (canceled)

47. (canceled)

48. The composition of claim 40, wherein the alkanolamine having one alkanol groups comprises one or more of monoethanolamine, 2-(2-Aminoethoxy)ethanol, N-methylethanolamine and monoisopropylamine.

49. The composition of claim 40, wherein the alkanolamine having one alkanol groups comprises monoethanolamine.

50. (canceled)

51. (canceled)

52. The composition of claim 40, wherein the alpha hydroxy acid is selected from the group of glycolic acid, lactic acid, tartaric acid, citric acid, malic acid, gluconic acid, glyceric acid, mandelic acid, tartronic acid, saccharic acid and dihydroxymalonic acid and mixtures thereof.

53. The composition of claim 40, wherein the alpha hydroxy acid comprises gluconic acid.

54-62. (canceled)

63. The composition of claim 40, wherein the composition comprises between approximately 2.5% by weight and approximately 25% weight of the alpha hydroxy acid.

64-66. (canceled)

67. The composition of claim 40, wherein the composition comprises approximately 10% weight of the alpha hydroxy acid.

68. The composition of claim 40, wherein the composition comprises between approximately 2.5% by weight and approximately 25% weight of gluconic acid.

69-71. (canceled)

72. The composition of claim 40, wherein the composition comprises approximately 10% weight of gluconic acid.

73. The composition of claim 40, wherein the composition comprises approximately 6% weight of catechol.

74. (canceled)

75. The composition of claim 40, wherein the composition comprises approximately 3% weight of gallic acid.

76. The composition of claim 40, wherein the composition comprises between approximately 5% by weight and 15% by weight in combination of catechol and gallic acid.

77-81. (canceled)

82. The composition of claim 40, wherein the composition comprises approximately 10% by weight in combination of catechol and gallic acid.

83. The composition of claim 40, wherein the composition comprises (i) approximately 20% by weight of triethanolamine and (ii) between approximately 35% by weight and approximately 45% weight of monoethanolamine.

84. The composition of claim 40, wherein the composition comprises (i) approximately 20% by weight of triethanolamine, (ii) between approximately 35% by weight and approximately 45% weight of monoethanolamine and (iii) approximately 10% weight of gluconic acid.

85. The composition of claim 40, wherein the composition comprises (i) approximately 20% by weight of triethanolamine, (ii) between approximately 35% by weight and approximately 45% weight of monoethanolamine, (iii) approximately 10% weight of gluconic acid and (iv) approximately 9% by weight in combination of catechol and gallic acid.

86. A method of removing residues from a microelectronic device or semiconductor substrate comprising the step of contacting the device or substrate with the cleaning composition of claim 40.
